(19) United States
(12) Patent Application Publication
(10) Pub. No.: US 2024/0361395 A1
(43) Pub. Date: Oct. 31, 2024

(54) ELECTRONIC DEVICE

(71) Applicant: Samsung Electronics Co., Ltd., Suwon-si (KR)

(72) Inventors: Hyuk Rae PARK, Suwon-si (KR); Sang Bin MOON, Suwon-si (KR); Min Hwan SEO, Suwon-si (KR); Sang Beom KIM, Suwon-si (KR)

(73) Assignee: Samsung Electronics Co., Ltd., Suwon-si (KR)

(21) Appl. No.: 18/347,293

(22) Filed: Jul. 5, 2023

(30) Foreign Application Priority Data
Nov. 2, 2022 (KR) 10-2022-0144292

(51) Int. Cl. G01R 31/388; G01R 31/36; H01M 10/48; H02J 7/00

(52) U.S. Cl. CPC G01R 31/388; G01R 31/3646; H01M 10/48; H02J 7/0048

(57) ABSTRACT

An electronic device may comprise a battery configured to supply power, and processing circuitry configured to, calculate a state of charge (SOC) calculated value of the battery based on sensed battery condition information of the battery, generate an SOC reported value, which fluctuates between a desired first value and a desired second value, wherein the desired second value is lower than the desired first value, based on at least one of the SOC calculated value, a charging status of the battery, a fully charged voltage of the battery, and a fully discharged voltage of the battery, and control the electronic device based on the SOC reported value.

This U.S. non-provisional application claims the benefit of priority under 35 U.S.C. § 119 to Korean Patent Application No. 10-2022-0144292, filed on Nov. 2, 2022, in the Korean Intellectual Property Office, the disclosure of which is incorporated herein in its entirety by reference.

### BACKGROUND

Various example embodiments of the inventive concepts relate to an electronic device.

In an electronic device equipped with a lithium ion battery, a state of charge (SOC) value of the battery may be calculated using an electro-chemical thermal model (ECT) and/or an equivalent circuit model (ECM). Here, the actual SOC value of the battery may be calculated to increase and/or decrease sharply. However, when the SOC value of the battery displayed on a display panel increases and/or decreases sharply, a user of the electronic device may incorrectly believe that the battery is defective. In this regard, research is being conducted to improve the reliability of the battery and the electronic device equipped with the battery from a user's point of view by correcting the SOC value of the battery.

### SUMMARY

Various example embodiments of the inventive concepts provide an electronic device with improved reliability.

However, the example embodiments are not restricted to the ones set forth herein. The above and other aspects of the example embodiments of the inventive concepts will become more apparent to one of ordinary skill in the art to which the example embodiments of the inventive concepts pertain by referencing the detailed description of the example embodiments given below.

According to at least one example embodiment of the inventive concepts, there is a provided electronic device comprising a battery configured to supply power, and processing circuitry configured to, calculate a state of charge (SOC) calculated value of the battery based on sensed battery condition information of the battery, generate an SOC reported value, which fluctuates between a desired first value and a desired second value based on at least one of the SOC calculated value, a charging status of the battery, a fully charged voltage of the battery, and a fully discharged voltage of the battery, the desired second value being lower than the desired first value, and control the electronic device based on the SOC reported value.

According to at least one example embodiment of the inventive concepts, there is a provided electronic device comprising a battery configured to supply power, a display panel configured to display a remaining capacity of the battery, and processing circuitry configured to calculate a state of charge (SOC) calculated value of the battery based on sensed battery condition information of the battery, generate a SOC reported value, the SOC reported value fluctuating between a desired first SOC value and a desired second SOC value, based on at least one of the SOC calculated value, a charging status of the battery, a fully charged voltage of the battery, and a fully discharged voltage of the battery, the desired first SOC value being greater than the desired second SOC value, and display the SOC reported value on the display panel.

According to at least one example embodiment of the inventive concepts, there is a provided electronic device comprising a battery configured to supply power to the electronic device, a sensing device configured to sense battery condition information of the battery, processing circuitry configured to calculate a state of charge (SOC) calculated value of the battery based on the sensed battery condition information, derive a desired open circuit voltage (OCV) threshold based on the sensed battery condition information while in a current stabilization state during a discharging operation of the battery, compare an SOC value based on the desired OCV threshold with the SOC calculated value, and correct an amount of change in the SOC calculated value with respect to an amount of change in a used capacity of the battery based on the SOC calculated value and a charging status of the battery, and a display panel configured to display a remaining capacity of the battery based on the corrected amount of change in the SOC calculated value.

It should be noted that the effects of the example embodiments of the inventive concepts are not limited to those described above, and other effects of the example embodiments of the inventive concepts will be apparent from the following description.

### BRIEF DESCRIPTION OF THE DRAWINGS

These and/or other aspects will become apparent and more readily appreciated from the following description of various example embodiments of the inventive concepts, taken in conjunction with the accompanying drawings in which:

FIG. 1 is a block diagram of an electronic device according to some example embodiments.

FIG. 2 is an example diagram for explaining a state of charge (SOC) calculated value of a battery illustrated in FIG. 1 according to at least one example embodiment.

FIG. 3 is a block diagram of an SOC filter illustrated in FIG. 1 according to at least one example embodiment.

FIG. 4 is a flowchart illustrating the operation of the electronic device according to some example embodiments.

FIG. 5 is an example diagram for explaining an SOC calculated value and an SOC reported value of the battery illustrated in FIG. 1 according to at least one example embodiment.

FIGS. 6 and 7 are example diagrams for explaining a mapping module illustrated in FIG. 3 according to some example embodiments.

FIGS. 8 and 9 are flowcharts for explaining a scaling module illustrated in FIG. 3 according to some example embodiments.

FIGS. 10 and 11 are flowcharts for explaining a sticking module illustrated in FIG. 3 according to some example embodiments.

FIGS. 12 and 13 are flowcharts for explaining a holding module illustrated in FIG. 3 according to some example embodiments.

FIGS. 14 and 15 are flowcharts illustrating the operation of the electronic device including an open circuit voltage (OCV) prediction module illustrated in FIG. 3 according to some example embodiments.

FIG. 16 is an example diagram for explaining the operation of the OCV prediction module according to at least one example embodiment.

FIG. 17 is a flowchart illustrating an operation of deriving an optimal OCV and an SOC value according to the optimal OCV using the OCV prediction module according to at least one example embodiment.

### DETAILED DESCRIPTION

Hereinafter, an electronic device according to various example embodiments of the inventive concepts will be described with reference to the accompanying drawings.

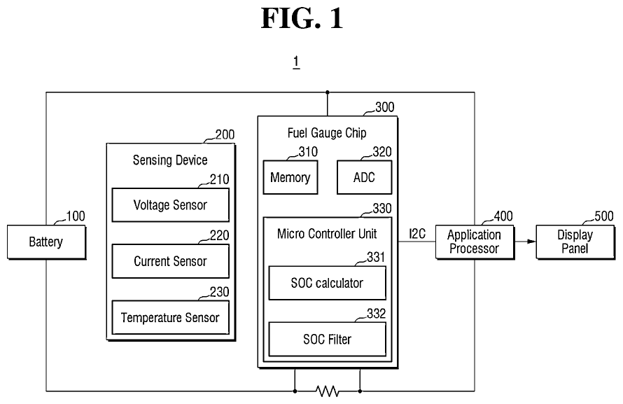

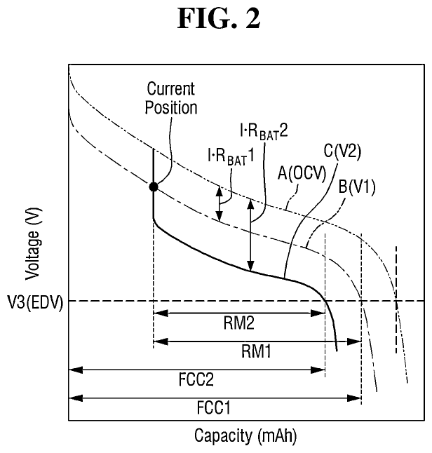

FIG. 1 is a block diagram of an electronic device 1 according to some example embodiments. FIG. 2 is an example diagram for explaining a state of charge (SOC) calculated value of a battery 100 illustrated in FIG. 1.

First, referring to FIG. 1, the electronic device 1 includes at least one battery 100 (e.g., an energy storage device, etc.), a sensing device 200 (e.g., at least one sensor, at least one sensing device, sensing circuitry, etc.), a fuel gauge chip 300 (e.g., fuel gauge circuitry, etc.), at least one application processor 400, and/or a display panel 500, etc. However, the example embodiments are not limited thereto, and the electronic device 1 may include other components in addition to the illustrated components, or may omit one or more of the illustrated components, etc. According to some example embodiments, one or more of the sensing device 200, the fuel gauge chip 300, and/or the application processor 400 may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

The battery 100 may store and/or generate a power supply voltage and provide the power supply voltage to the electronic device 1. In some example embodiments, the remaining capacity of the battery 100 (e.g., the amount of energy stored in the battery 100) may be expressed as a state of charge (SOC). The SOC may correspond to an indicator indicating the current stored energy level and/or the current charging status of the electronic device 1 which receives the power supply voltage from the battery 100, but is not limited thereto. A method of calculating an SOC value of the battery 100 will be described in detail later with reference to FIG. 2.

The sensing device 200 may include a voltage sensor 210, a current sensor 220, and/or a temperature sensor 230, etc., but the example embodiments are not limited thereto, and for example, may include an ohmmeter, etc. The voltage sensor 210, the current sensor 220, and/or the temperature sensor 230 may respectively sense the voltage, current, and/or temperature, etc., (e.g., battery condition information, current battery condition information, etc.) of the battery 100, and may send the sensed voltage, current, and/or temperature to the fuel gauge chip 300, etc., but the example embodiments are not limited thereto, and for example, may further sense a resistance of the battery 100, a wattage of the battery 100, a humidity associated with the battery 100, and/or other environmental values associated with the battery 100, etc.

The fuel gauge chip 300 (e.g., fuel gauge circuitry, etc.) may include a memory 310, an analog-digital converter (ADC) 320, and/or a micro controller unit (MCU) 330, etc., but is not limited thereto. The memory 310 may be implemented as, for example, a flash memory, but is not limited thereto. The memory 310 may store firmware and/or computer readable instructions for operating the fuel gauge chip 300. The ADC 320 may convert analog information (e.g., analog data) about and/or regarding the voltage, current, and/or temperature, etc., of the battery 100 received from the sensing device 200 into digital information (e.g., digital data) that may be recognized by the MCU 330, etc. The ADC 320 may send the digital information about the voltage, current, and/or temperature of the battery 100 to the MCU 330, but is not limited thereto.

The MCU 330 may include an SOC calculator 331 and/or an SOC filter 332, etc., but is not limited thereto. The SOC calculator 331 may calculate the SOC of the battery 100 based on the information about the voltage, current, and/or temperature, etc., of the battery 100 received from the ADC 320 and generate an SOC calculated value SOC_CAL. In some example embodiments, the SOC calculator 331 may calculate the SOC of the battery 100 based on an electro-chemical thermal model (ECT), but is not limited thereto. In addition, in some example embodiments, the SOC calculator 331 may calculate the SOC of the battery 100 based on an equivalent circuit model (ECM), but is not limited thereto. Some or all of the operation of the MCU 330 may be implemented in the form of software, such as firmware and/or computer readable instructions, executed by processing circuitry, so that the operations of the SOC calculator 331 and the SOC filter 332, which consume a relatively large amount of computation, may be performed with lower power consumption. In addition, since the operations of the SOC calculator 331 and the SOC filter 332 are performed independently of the application processor 400, a burden on processor resource allocation, memory resource allocation, and/or operation of the application processor 400 may be reduced.

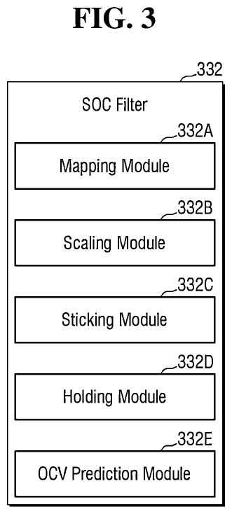

The SOC filter 332 may generate an SOC reported value SOC_RE of the battery 100 based on at least one of the SOC calculated value SOC_CAL, charging status, fully charged voltage, and/or fully discharged voltage of the battery 100, etc. The SOC reported value SOC_RE may fluctuate between a desired and/or predetermined maximum value (e.g., a desired first SOC value, a desired first SOC_RE value, a desired first value, etc.) and a desired and/or predetermined minimum value (e.g., a desired second SOC value, a desired second SOC_RE value, a desired second value, etc.). In some example embodiments, the desired and/or predetermined maximum value may be set to 100%, and the desired and/or predetermined minimum value may be set to 0%, but the example embodiments are not limited thereto, and for example, the SOC_RE values may be set to other desired values, such as 80% and 20%, etc. Here, a user of the electronic device 1 receiving a power supply voltage from the battery 100 may check the SOC reported value SOC_RE that fluctuates between the desired values, e.g., 0% and 100%, etc. The SOC filter 332 may provide the SOC reported value SOC_RE to the application processor 400 through inter-integrated circuit (I2C) communication, but is not limited thereto. The detailed configuration of the SOC filter 332 will be described later with reference to FIG. 3.

The application processor 400 may control the overall operation of the electronic device 1. For example, the application processor 400 may control the operations of the battery 100, the sensing device 200, the fuel gauge chip 300, and/or the display panel 500, etc., included in the electronic device 1. In addition, the application processor 400 may control the display panel 500 to display the SOC reported value SOC_RE. The display panel 500 may display the remaining capacity of the battery 100, that is, the SOC reported value SOC_RE.

Next, referring to FIG. 2, A, B, and C are graphs (e.g., curves, etc.) illustrating changes in the voltage of the battery 100 with respect to the capacity of the battery 100 when the battery 100 is discharged, but the example embodiments are not limited thereto. A is a graph (e.g., curve) illustrating the change in an open circuit voltage (OCV) with respect to the capacity of the battery 100 when no load is applied to the battery 100, for example, when the electronic device 1 operates in a low power state, etc. B is a graph (e.g., curve) illustrating the change in the voltage V1 of the battery 100 with respect to the capacity of the battery 100 when a first load Load1 is applied to the battery 100 as the electronic device 1 performs a first operation, etc. C is a graph (e.g., curve) illustrating the change In the voltage V2 of the battery 100 with respect to the capacity of the battery 100 when a second load Load2 is applied to the battery 100 as the electronic device 1 performs a second operation, etc. V3 (e.g., an end of voltage (EDV)) is a fully discharged voltage of the battery 100, that is, a voltage when the battery 100 is in a fully discharged state, etc.

As illustrated in FIG. 2, when the electronic device 1 performs the first operation, the voltage V1 of the battery 100 is reduced from the OCV by an amount obtained by multiplying a resistance value R_BAT1 of the battery 100 by a current I of the battery 100. In addition, when the electronic device 1 performs the second operation, the voltage V2 of the battery 100 is reduced from the OCV by an amount obtained by multiplying a resistance value R_BAT2 of the battery 100 by the current I of the battery 100, but the example embodiments are not limited thereto. In some example embodiments, if the second load Load2 applied to the battery 100 when the electronic device 1 performs the second operation is greater than the first load Load1 applied to the battery 100 when the electronic device 1 performs the first operation, the voltage V2 of the battery 100 may be smaller than the voltage V1 of the battery 100, but the example embodiments are not limited thereto.

Here, an SOC value of the battery 100 may be expressed as a percentage of the remain capacity RM (e.g., the remaining capacity) of the battery 100 to full charge capacity FCC of the battery 100. Referring to FIG. 2, the full charge capacity FCC of the battery 100 corresponds to the capacity used by the battery 100 until the voltage of the battery 100 reaches the fully discharged voltage EDV from an initial state. That is, FCC corresponds to the usable capacity of the battery 100 when the battery 100 is fully charged. In addition, the remain capacity RM of the battery 100 corresponds to the current usable capacity of the battery 100 until the voltage of the battery 100 reaches the fully discharged voltage EDV from a current capacity position of the battery 100.

For example, when the electronic device 1 performs the first operation, and assuming FCC1 is 1000 mAh and RM1 is 600 mAh, the SOC1 is calculated as 60%. In addition, when the electronic device 1 performs the second operation, and assuming FCC2 is 900 mAh and RM2 is 500 mAh, SOC2 is calculated as 55.5%. Like this, when the electronic device 1 performs the first operation and then the second operation having a greater load than the first operation, the SOC of the battery 100 may decrease sharply from 60% to 55.5%.

When an SOC jump in which the SOC value of the battery 100 increases and/or decreases sharply occurs as described above, the reliability of the electronic device 1 and/or the reliability of the battery 100 of the electronic device 1 may deteriorate. Further, a user's perception of the reliability of the electronic device 1 and/or the battery 100 may also deteriorate. In this regard, in some example embodiments, the SOC filter 332 may generate the SOC reported value SOC_RE, from which the SOC jump is removed based on the SOC calculated value SOC_CAL generated by the SOC calculator 331. Accordingly, the reliability of the electronic device 1 and/or the battery 100 may be improved and/or increased.

FIG. 3 is a block diagram of the SOC filter 332 illustrated in FIG. 1 according to at least one example embodiment.

Referring to FIG. 3, the SOC filter 332 may include a mapping module 332A, a scaling module 332B, a sticking module 332C, a holding module 332D, and/or an OCV prediction module 332E, etc., but the example embodiments are not limited thereto. A case where a desired and/or predetermined maximum value of the SOC reported value SOC_RE is 100% and a desired and/or predetermined minimum value is 0% will be described below as an example. However, the example embodiments are not limited thereto, and the desired and/or predetermined maximum value (e.g., the desired first SOC_RE value, etc.) and the desired and/or predetermined minimum value (e.g., the desired second SOC_RE value, etc.) of the SOC reported value SOC_RE may vary.

The mapping module 332A may correct (hereinafter, referred to as remap) the amount of change in the SOC calculated value SOC_CAL with respect to the amount of change in the used capacity of the battery 100 based on the SOC calculated value SOC_CAL and charging status of the battery 100, etc., but is not limited thereto. Specifically, the mapping module 332A may make the slope of the SOC calculated value SOC_CAL gentle and may remove an SOC jump in which the SOC calculated value SOC_CAL increases and/or decreases sharply, so that the slope of the SOC reported value SOC_RE becomes linear, or in other words, the slope of the SOC reported value SOC_RE is greater than a desired slope increase threshold value and/or the slope of the SOC_RE is less than a desired slope decrease threshold value, etc. In some example embodiments, the mapping module 332A may remap the slope of the SOC calculated value SOC_CAL when the charging status of the battery 100 is changed, for example, when the battery 100 is changed from a charged state to a discharged state (e.g., a charging state to a discharging state), and/or from the discharged state to the charged state (e.g., a discharging state to a charging state). That is, the mapping module 332A may make the slope of the SOC calculated value SOC_CAL gentle in response to a sharp change in the SOC calculated value SOC_CAL when the charging status of the battery 100 is changed.

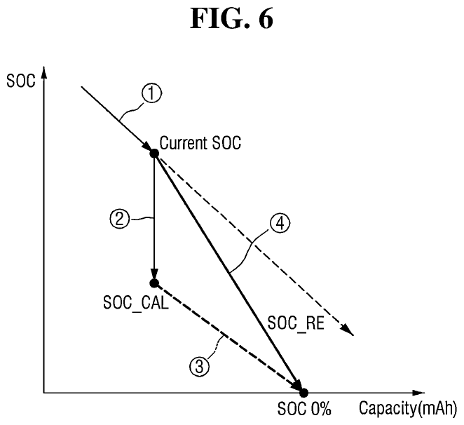

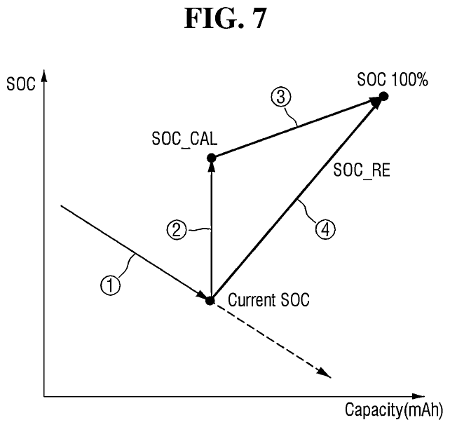

In addition, in some example embodiments, the mapping module 332A may correct the amount of change in the SOC calculated value SOC_CAL with respect to the amount of change in the used capacity of the battery 100 in response to a change in the fully discharged voltage EDV of the battery 100. In addition, in some example embodiments, the mapping module 100 may correct the slope of the SOC calculated value SOC_CAL at desired and/or predetermined time intervals (e.g., at intervals of 200 seconds, etc.). The detailed operation of the mapping module 332A will be described later with reference to FIGS. 6 and 7.

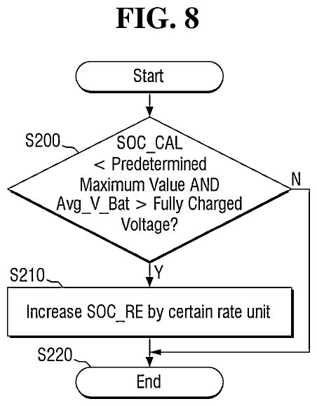

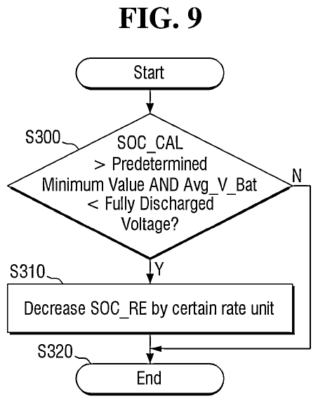

The scaling module 332B may correct the SOC reported value SOC_RE to make it rapidly reach 100% or 0% by repeatedly increasing and/or decreasing the SOC reported value SOC_RE by a certain percentage unit (e.g., a desired percentage amount, a set percentage amount, etc.) in response to the SOC calculated value SOC_CAL not reaching 100% or 0% while the average voltage of the battery 100 has already reached the fully charged voltage and/or the fully discharged voltage. The detailed operation of the scaling module 332B will be described later with reference to FIGS. 8 and 9.

In response to the SOC calculated value SOC_CAL being greater than 100%, the sticking module 332C may stick the SOC reported value SOC_RE to 100% in a range where the SOC calculated value SOC_CAL exceeds 100%, or in other words, the sticking module 332C may set the SOC reported value SOC_RE as 100% when the SOC calculated value SOC_CAL is greater than 100%, but is not limited thereto. In addition, when the SOC calculated value SOC_CAL falls within the range of 100% or less, the mapping module 332A may set a point at which the SOC reported value SOC_RE starts to decrease to a point at which the SOC reported value SOC_RE is 100% by remapping the slope of the SOC calculated value SOC_CAL, etc.

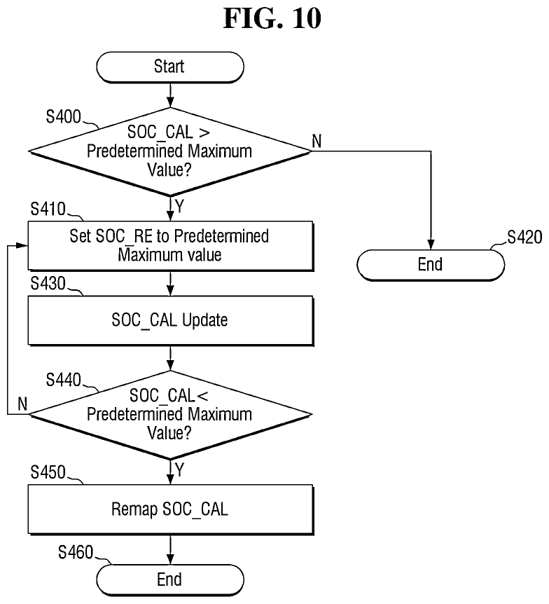

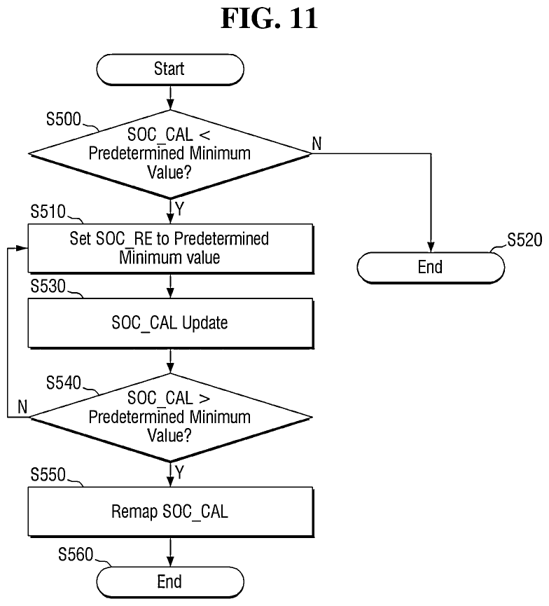

In addition, in some example embodiments, in response to the SOC calculated value SOC_CAL being less than 0%, the sticking module 332C may stick the SOC reported value SOC_RE to 0% in a range where the SOC calculated value SOC_CAL is less than 0%, or in other words, the sticking module 332C may set the SOC reported value SOC_RE as 0% when the SOC calculated value SOC_CAL is less than 0%, but is not limited thereto. In addition, when the SOC calculated value SOC_CAL falls within the range of 0% or greater, the mapping module 332A may set a point at which the SOC reported value SOC_RE starts to increase to a point at which the SOC reported value SOC_RE is 0% by remapping the slope of the SOC calculated value SOC_CAL, etc. The detailed operation of the sticking module 332C will be described later with reference to FIGS. 10 and 11.

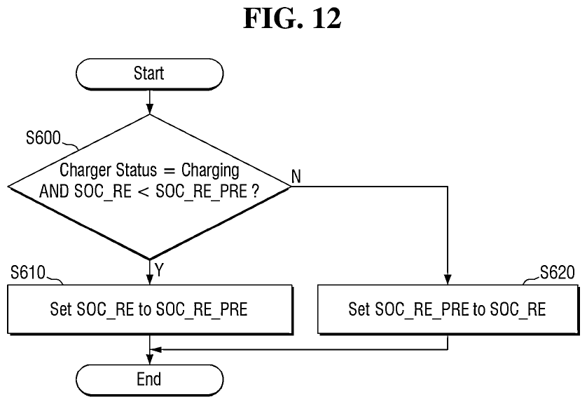

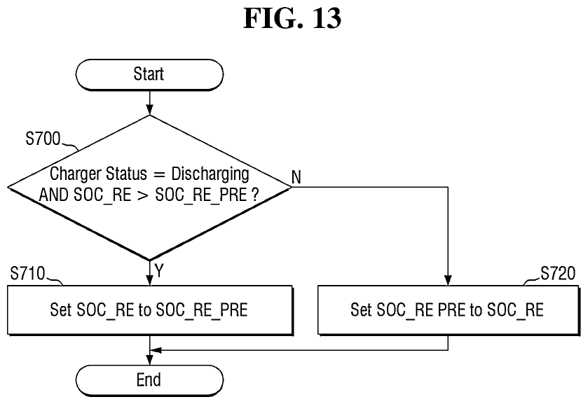

The holding module 332D may correct the SOC reported value SOC_RE to a value before the SOC reported value SOC_RE decreases and/or increases in order to reduce and/or prevent the SOC reported value SOC_RE from decreasing while the battery 100 is being charged and/or may reduce and/or prevent the SOC_RE from increasing while the battery 100 is being discharged. The detailed operation of the holding module 332D will be described later with reference to FIGS. 12 and 13.

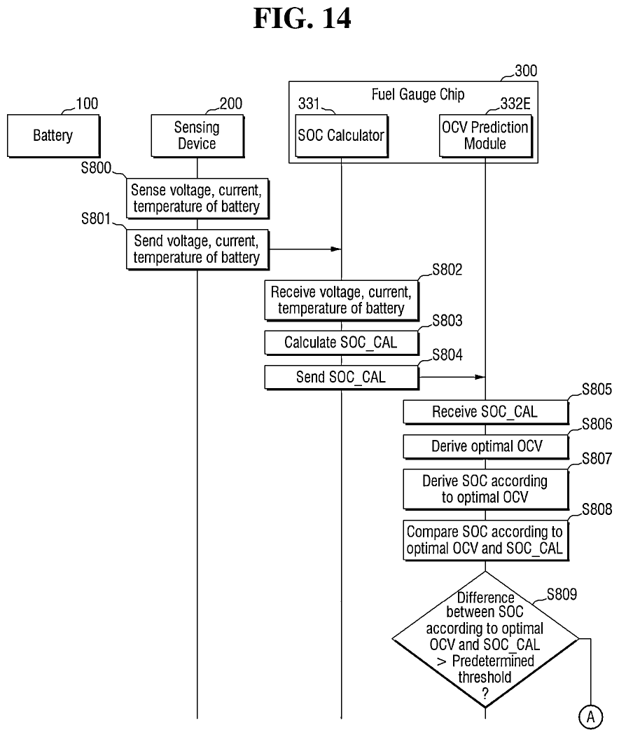

The OCV prediction module 332E may derive an optimal OCV (e.g., a desired OCV threshold, a desired OCV value, etc.), which decreases and/or minimizes an OCV error of the battery 100, based on the voltage of the battery 100 in a current stabilization state during the discharging of the battery 100, and may compare an SOC value according to and/or based on the optimal OCV with the SOC calculated value SOC_CAL generated by the SOC calculator 331 (see FIG. 1). In addition, in some example embodiments, in response to a difference between the SOC value according to the optimal OCV and the SOC calculated value SOC_CAL being equal to or greater than a desired and/or predetermined threshold value, the OCV prediction module 332E may correct the SOC calculated value SOC_CAL to reduce and/or minimize the difference between the SOC calculated value SOC_CAL and the SOC value according to the optimal OCV, etc. The detailed operation of the OCV prediction module 332E will be described later with reference to FIGS. 14 through 17.

As described above, since the operation of the SOC filter 332, which causes a relatively large amount of computation, is implemented in the form of software such as firmware and/or computer readable instructions, etc., an operation of generating the SOC reported value SOC_RE based on the SOC calculated value SOC_CAL of the battery 100 may be performed with lower power consumption.

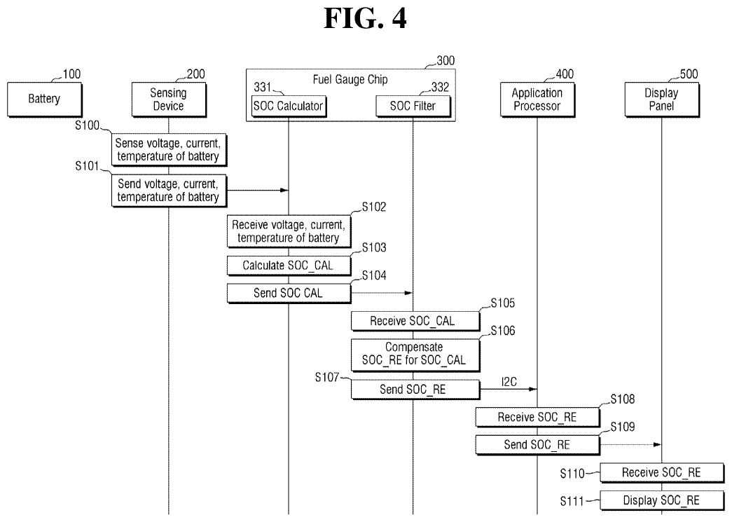

FIG. 4 is a flowchart illustrating the operation of the electronic device 1 according to some example embodiments.

Referring to FIG. 4, the sensing device 200 (e.g., sensor, etc.) senses battery condition information, e.g., the voltage, current, and/or temperature, etc., of the battery 100, (operation S100) and sends the battery condition information, e.g., the sensed voltage, current, and/or temperature, etc., to the SOC calculator 331 (operation S101). The SOC calculator 331 receives the battery condition information, e.g., the voltage, current and temperature of the battery 100 (operation S102), and calculates the SOC calculated value SOC_CAL of the battery 100 based on the received battery condition information (operation S103). Then, the SOC calculator 331 sends the SOC calculated value SOC_CAL to the SOC filter 332 (operation S104).

The SOC filter 332 receives the SOC calculated value SOC_CAL (operation S105) and generates the SOC reported value SOC_RE based on at least one of the SOC calculated value SOC_CAL, charging status, fully charged voltage, and/or fully discharged voltage of the battery 100, etc., (operation S106). Then, the SOC filter 332 sends the SOC reported value SOC_RE to the application processor 400 through I2C communication (operation S107), but the example embodiments are not limited thereto. The application processor 400 receives the SOC reported value SOC_RE (operation S108) and sends the SOC reported value SOC_RE to the display panel 500 (operation S109). The display panel 500 receives the SOC reported value SOC_RE (operation S110) and finally displays the SOC reported value SOC_RE (operation S111), etc.

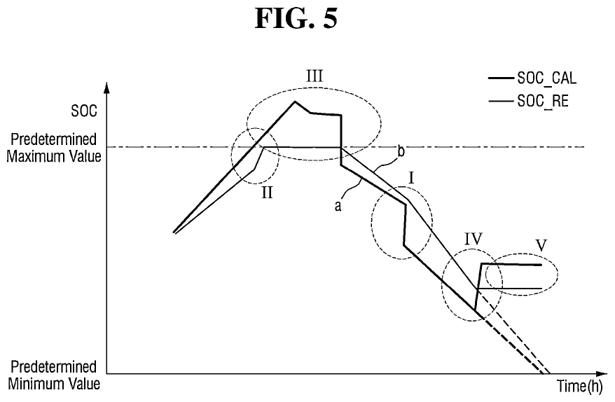

FIG. 5 is an example diagram for explaining the SOC calculated value SOC_CAL and the SOC reported value SOC_RE of the battery 100 illustrated in FIG. 1 according to at least one example embodiment.

Referring to FIG. 5, a and b are graphs illustrating changes in the SOC of the battery 100 with respect to time when the battery 100 is changed from a charged state to a discharged state, but the example embodiments are not limited thereto. Specifically, a is a graph illustrating the SOC calculated value SOC_CAL generated by the SOC calculator 331, and b is a graph illustrating the SOC reported value SOC_RE generated by correcting the SOC calculated value SOC_CAL using the SOC filter 332, but the example embodiments are not limited thereto. The SOC reported value SOC_RE fluctuates between a desired and/or predetermined maximum value (e.g., 100%) (e.g., a first SOC_RE value, etc.) and a desired and/or predetermined minimum value (e.g., 0%) (e.g., a second SOC_RE value, etc.). A case where the desired and/or predetermined maximum value of the SOC reported value SOC_RE is 100% and the desired and/or predetermined minimum value is 0% will be described below as an example, but the example embodiments are not limited thereto, and other percentage values may be used.

As illustrated in FIG. 5, the SOC filter 332 (see FIG. 4) may make the graph a linear like the graph b by generating the SOC reported value SOC_RE based on the SOC calculated value SOC_CAL: (I) when the SOC calculated value SOC_CAL generated by the SOC calculator 331 (see FIG. 4) decreases (and/or increases) sharply: (II) when the battery 100 reaches the fully charged voltage, but the SOC calculated value SOC_CAL does not reach 100% (and/or when the battery 100 reaches the fully discharged voltage, but the SOC calculated value SOC_CAL is greater than 0%); (III) when the SOC calculated value SOC_CAL is greater than 100% (or less than 0%); (IV) and/or when the SOC calculated value SOC_CAL increases during discharging of the battery 100 (and/or when the SOC calculated value SOC_CAL decreases during charging of the battery 100), but the example embodiments are not limited thereto.

In some example embodiments, since the SOC filter 332 (see FIG. 4) generates the SOC reported value SOC_RE based on the SOC calculated value SOC_CAL received from the SOC calculator 331 (see FIG. 4) as described above, the confidence of a user of the electronic device 1 (see FIG. 1) in the battery 100 (see FIG. 4) may be improved and/or increased.

FIGS. 6 and 7 are example diagrams for explaining the mapping module 332A illustrated in FIG. 3 according to at least one example embodiment.

First, referring to FIG. 6, while the battery 100 (see FIG. 1) is being discharged, the SOC calculated value SOC_CAL of the battery 100 (see FIG. 1) may decrease sharply (\textcircled{1}->\textcircled{2}->\textcircled{3}), but the example embodiments are not limited thereto. Like this, as the load applied to the battery 100 (see FIG. 1) increases, the SOC calculated value SOC_CAL of the battery 100 (see FIG. 1) may be calculated to decrease sharply. However, when the remaining capacity of the battery 100 (see FIG. 1) decreases sharply, a user of the electronic device 1 (see FIG. 1) may misunderstand that the battery 100 (see FIG. 1) is defective and/or unreliable, etc.

Therefore, the mapping module 332A (see FIG. 3) may correct the SOC calculated value SOC_CAL to the SOC reported value SOC_RE by correcting and/or adjusting the amount of change in the SOC calculated value SOC_CAL with respect to the amount of change in the used capacity of the battery 100 (see FIG. 1), that is, the slope of the SOC calculated value SOC_CAL to be gentle, e.g., decrease the rate of change of the slope in response to the slope exceeding a desired SOC_RE value, etc. In some example embodiments, as illustrated in FIG. 6, in a Cartesian coordinate system having the capacity of the battery 100 (see FIG. 1) as the x-axis and the SOC value as the y-axis, a straight line 4) connecting a point representing a current SOC value and a point representing a desired and/or predetermined minimum value (e.g., SOC 0%) of the SOC reported value SOC_RE may be corrected to the SOC reported value SOC_RE, etc.

Like this, by making the slope of the SOC calculated value SOC_CAL gentle (e.g., decreasing the rate of change of the slope, etc.) in response to a sharp decrease (e.g., a decrease in the slope below a desired slope decrease threshold, etc.) in the SOC calculated value SOC_CAL during discharging of the battery 100 (see FIG. 1), the mapping module 332A (see FIG. 3) may improve a user's confidence in the electronic device 1 (see FIG. 1) and/or the battery 100 (see FIG. 1).

Next, referring to FIG. 7, when the battery 100 (see FIG. 1) is changed from a discharged state to a charged state (e.g., from an operational state to a recharging state, a first state to a second state, etc.), the SOC calculated value SOC_CAL of the battery 100 (see FIG. 1) may increase sharply (\textcircled{1}->\textcircled{2}->\textcircled{3}). Like this, when the battery 100 (see FIG. 1) in the discharged state is suddenly changed to the charged state, the SOC calculated value SOC_CAL of the battery 100 (see FIG. 1) may actually be calculated to increase sharply. However, when the remaining capacity of the battery 100 (see FIG. 1) increases sharply, the user of the electronic device 1 (see FIG. 1) may misunderstand that the battery 100 (see FIG. 1) is defective.

Therefore, the mapping module 332A may correct the SOC calculated value SOC_CAL to the SOC reported value SOC_RE by correcting the amount of change in the SOC calculated value SOC_CAL with respect to the amount of change in the used capacity of the battery 100 (see FIG. 1), that is, the slope of the SOC calculated value SOC_CAL to be gentle (e.g., lowering the rate of change of the slope, etc.). In some example embodiments, as illustrated in FIG. 7, in a Cartesian coordinate system having the capacity of the battery 100 (see FIG. 1) as the x-axis and the SOC value as the y-axis, a straight line (4) connecting a point representing a current SOC value and a point representing a desired and/or predetermined maximum value (e.g., SOC 100%) of the SOC reported value SOC_RE may be corrected to the SOC reported value SOC_RE, etc.

Like this, by making the slope of the SOC calculated value SOC_CAL gentle in response to a sharp increase (e.g., an increase in the slope exceeding a desired slope increase threshold, etc.) in the SOC calculated value SOC_CAL when the battery 100 (see FIG. 1) is changed from the discharged state to the charged state (e.g., from the operational state to the recharging state, etc.), the mapping module 332A may improve the user's confidence of the electronic device 1 (see FIG. 1) and/or the battery 100 (see FIG. 1), etc.

FIGS. 8 and 9 are flowcharts for explaining the scaling module 332B illustrated in FIG. 3 according to at least one example embodiment.

First, referring to FIG. 8, the scaling module 332B determines whether the SOC calculated value SOC_CAL is smaller than a desired and/or predetermined maximum value (e.g., 100%) and, at the same time, determines whether the voltage Avg_V_Bat of the battery 100 is greater than a fully charged voltage (operation S200). If the scaling module 332B determines that the SOC calculated value SOC_CAL is smaller than the desired and/or predetermined maximum value while the voltage Avg_V_Bat of the battery 100 is greater than the fully charged voltage (Y in operation S200), the scaling module 332B repeatedly increases the SOC reported value SOC_RE by a certain percentage unit and/or desired percentage value, etc. (operation S210). If the scaling module 332B determines that the SOC calculated value SOC_CAL is not smaller than the desired and/or predetermined maximum value and/or that the voltage of the battery 100 is not greater than the fully charged voltage (N in operation S200), the scaling module 332B ends its operation (operation S220).

Like this, when the battery 100 is fully charged, that is, when the average voltage of the battery 100 has already reached the fully charged voltage, it is natural from a user's point of view to display the SOC value of the battery 100 as the desired and/or predetermined maximum value (e.g., 100%). Therefore, if the average voltage of the battery 100 exceeds the voltage at a time when the battery 100 is fully charged, that is, the fully charged voltage, but the SOC calculated value SOC_CAL is smaller than the desired and/or predetermined maximum value, the user of the electronic device 1 (see FIG. 1) may misunderstand that the battery 100 is defective.

In this case, the scaling module 332B may repeatedly increase the SOC reported value SOC_RE by a certain percentage unit (e.g., desired percentage value, etc.) so that the SOC reported value SOC_RE rapidly reaches the desired and/or predetermined maximum value. As a result, as shown in II of FIG. 5, the SOC reported value SOC_RE may reach the desired and/or predetermined maximum value faster than the SOC calculated value SOC_CAL. Consequently, the confidence of the user of the electronic device 1 (see FIG. 1) in the battery 100 may be improved.

Next, referring to FIG. 9, the scaling module 332B determines whether the SOC calculated value SOC_CAL is greater than a desired and/or predetermined minimum value (e.g., 0%) and, at the same time, determines whether the average voltage Avg_V_Bat of the battery 100 is smaller than a fully discharged voltage (operation S300). If the scaling module 332B determines that the SOC calculated value SOC_CAL is greater than the desired and/or predetermined minimum value while the average voltage Avg_V_Bat of the battery 100 is smaller than the fully discharged voltage (Y in operation S300), the scaling module 332B repeatedly decreases the SOC reported value SOC_RE by a certain percentage unit (operation S310). If the scaling module 332B determines that the SOC calculated value SOC_CAL is not greater than the desired and/or predetermined minimum value and/or that the average voltage of the battery 100 is not smaller than the fully discharged voltage (N in operation S300), the scaling module 332B ends its operation (operation S320).

Like this, when the battery 100 is fully discharged, that is, when the average voltage of the battery 100 has already reached the fully discharged voltage, it is natural from the user's point of view to display the SOC value of the battery 100 as the desired and/or predetermined minimum value (e.g., 0%). Therefore, if the average voltage of the battery 100 is smaller than the voltage at a time when the battery 100 is fully discharged, that is, the fully discharged voltage, but the SOC calculated value SOC_CAL is greater than the desired and/or predetermined minimum value, the user of the electronic device 1 (see FIG. 1) may misunderstand that the battery 100 is defective.

In this case, the scaling module 332B may repeatedly and/or decrease the SOC reported value SOC_RE by a certain percentage unit (e.g., desired percentage amount, etc.) so that the SOC reported value SOC_RE rapidly reaches the desired and/or predetermined minimum value. As a result, the SOC reported value SOC_RE may reach the desired and/or predetermined minimum value faster than the SOC calculated value SOC_CAL. Consequently, the confidence of the user of the electronic device 1 (see FIG. 1) in the battery 100 may be improved.

FIGS. 10 and 11 are flowcharts for explaining the sticking module 332C illustrated in FIG. 3 according to at least one example embodiment.

First, referring to FIG. 10, the sticking module 332C determines whether the SOC calculated value SOC_CAL is greater than a desired and/or predetermined maximum value (operation S400). If the sticking module 332C determines that the SOC calculated value SOC_CAL is greater than the desired and/or predetermined maximum value (Y in operation S400), the sticking module 332C sets the SOC reported value SOC_RE to the desired and/or predetermined maximum value by correcting the SOC calculated value SOC_CAL (operation S410). If the sticking module 332C determines that the SOC calculated value SOC_CAL is not greater than the desired and/or predetermined maximum value (N in operation S400), the sticking module 332C ends its operation (operation S420).

Next, information about and/or regarding the SOC calculated value SOC_CAL is updated (operation S430), and then the sticking module 332C again determines whether the SOC calculated value SOC_CAL decreased below the desired and/or predetermined maximum value (operation S440). If the sticking module 332C determines the SOC calculated value (SOC_CAL) decreased below the desired and/or predetermined maximum value (Y in operation S440), the mapping module 332A sets a point at which the SOC reported value SOC_RE starts to decreases to a point at which the SOC reported value SOC_RE is the desired and/or predetermined maximum value by remapping the slope of the SOC calculated value SOC_CA (operation S450). Then, the sticking module 332C and the mapping module 332A end their operation (operation S460). If the sticking module 332C determines the SOC calculated value SOC_CAL did not decrease below the desired and/or predetermined maximum value (N in operation S440), the sticking module 332C continuously sets the SOC reported value SOC_RE to the desired and/or predetermined maximum value (operation S410).

Like this, when the battery 100 is fully charged, it is natural from a user's point of view to display the SOC value of the battery 100 as the desired and/or predetermined maximum value, e.g., 100%. When the battery 100 is charged, even if the SOC value of the battery 100 is actually calculated as 105%, e.g., exceeding 100%, if the SOC value of the battery 100 is displayed as 105%, the user may misunderstand that the battery 100 is defective. Thus, when the SOC calculated value SOC_CAL exceeds the desired and/or predetermined maximum value, the sticking module 332C may stick the SOC reported value SOC_RE to the desired and/or predetermined maximum value as shown in III of FIG. 5.

In addition, when the SOC calculated value SOC_CAL decreases below the desired and/or predetermined maximum value, the slope of the SOC calculated value SOC_CAL may change rapidly. Therefore, the mapping module 332A may make the slope of the SOC calculated value SOC_CAL gentle and may set a point at which the SOC reported value SOC_RE starts to decrease to a point at which the SOC reported value SOC_RE is the desired and/or predetermined maximum value. Accordingly, the confidence of the user of the electronic device 1 (see FIG. 1) in the battery 100 may be improved.

Next, referring to FIG. 11, the sticking module 332C determines whether the SOC calculated value SOC_CAL is smaller than a desired and/or predetermined minimum value (operation S500). If the sticking module 332C determines that the SOC calculated value SOC_CAL is smaller than the desired and/or predetermined minimum value (Y in operation S500), the sticking module 332C sets the SOC reported value SOC_RE to the desired and/or predetermined minimum value by correcting the SOC calculated value SOC_CAL (operation S510). If the sticking module 332C determines that the SOC calculated value SOC_CAL is not smaller than the desired and/or predetermined minimum value (N in operation S500), the sticking module 332C ends its operation (operation S520).

Next, information about and/or regarding the SOC calculated value SOC_CAL is updated (operation S530), and then the sticking module 332C determines whether the SOC calculated value SOC_CAL increased above the desired and/or predetermined minimum value (operation S540). If the sticking module 332C determines the SOC calculated value SOC_CAL increased above the desired and/or predetermined minimum value (Y in operation S540), the mapping module 332A sets a point at which the SOC reported value SOC_RE starts to increase to a point at which the SOC reported value SOC_RE is the desired and/or predetermined minimum value by remapping the slope of the SOC calculated value SOC_CAL (operation S550). Then, the sticking module 332C and the mapping module 332A end their operation (operation S560). If the sticking module 332C determines the SOC calculated value SOC_CAL did not increase above the desired and/or predetermined minimum value (N in operation S540), the sticking module 332C continuously sets the SOC reported value SOC_RE to the desired and/or predetermined minimum value (operation S510).

Like this, when the battery 100 is fully discharged, it is natural from the user's point of view to display the SOC value of the battery 100 as the desired and/or predetermined minimum value, e.g., 0%. When the battery 100 is discharged, even if the SOC value of the battery 100 is actually calculated as a negative value, if the SOC value of the battery 100 is displayed as a negative value, the user may misunderstand that the battery 100 is defective. Thus, when the SOC calculated value SOC_CAL is smaller than the desired and/or predetermined minimum value, the sticking module 332C may stick the SOC reported value SOC_RE to the desired and/or predetermined minimum value. In addition, when the SOC calculated value SOC_CAL increases above the desired and/or predetermined minimum value, the slope of the SOC calculated value SOC_CAL may change rapidly. Therefore, the mapping module 332A may make the slope of the SOC calculated value SOC_CAL gentle and may set a point at which the SOC reported value SOC_RE starts to increase to a point at which the SOC reported value SOC_RE is the desired and/or predetermined minimum value. Accordingly, the confidence of the user of the electronic device 1 (see FIG. 1) in the battery 100 may be improved.

FIGS. 12 and 13 are flowcharts for explaining the holding module 332D illustrated in FIG. 3 according to at least one example embodiment.

First, referring to FIG. 12, the holding module 332D determines whether the battery 100 is being charged and determines whether the SOC reported value SOC_RE is smaller than a previous SOC reported value SOC_RE_PRE (operation S600). If the holding module 332D determines that the battery 100 is being charged and that the SOC reported value SOC_RE is smaller than the previous SOC reported value SOC_RE_PRE (Y in operation S600), the SOC reported value SOC_RE is set to the previous SOC reported value SOC_RE_PRE (operation S610). If the holding module 332D determines that the SOC reported value SOC_RE is not smaller than the previous SOC reported value SOC_RE_PRE (N in operation S610), the previous SOC reported value SOC_RE_PRE is set to the SOC reported value SOC_RE (operation S620).

Like this, when the battery 100 is being charged, it is natural from a user's point of view to display the SOC value of the battery 100 as increasing. When the battery 100 is being charged, even if the SOC value of the battery 100 is actually calculated to decrease, if the SOC value of the battery 100 is displayed as decreasing, the user may misunderstand and believe that the battery 100 is defective and/or unreliable. Thus, when the battery 100 is being charged, the holding module 332D may set the SOC reported value SOC_RE to the previous SOC reported value SOC_RE_PRE in response to the SOC reported value SOC_RE being smaller than the previous SOC reported value SOC_RE_PRE, etc.

In this way, by reducing and/or preventing the SOC reported value SOC_RE from decreasing while the battery 100 is being charged, it is possible to improve the confidence of the user of the electronic device 1 (see FIG. 1) and/or in the battery 100. In addition, in response to an increase in the SOC reported value SOC_RE while the battery 100 is being charged, the holding module 332D may set the previous SOC reported value SOC_RE_PRE to the SOC reported value SOC_RE and set the increased SOC reported value SOC_RE as it is. Accordingly, when the battery 100 is being charged, the SOC reported value SOC_RE may be displayed to the user of the electronic device 1 (see FIG. 1) as increasing.

Next, referring to FIG. 13, the holding module 332D determines whether the battery 100 is being discharged and determines whether the SOC reported value SOC_RE is greater than the previous SOC reported value SOC_RE_PRE (operation S700). If the holding module 332D determines that the battery 100 is being discharged and that the SOC reported value SOC_RE is greater than the previous SOC reported value SOC_RE_PRE (Y in operation S700), the SOC reported value SOC_RE is set to the previous SOC reported value SOC_RE_PRE (operation S710). If the holding module 332D determines that the SOC reported value SOC_RE is not greater than the previous SOC reported value SOC_RE_PRE (N in operation S700), the previous SOC reported value SOC_RE_PRE is set to the SOC reported value SOC_RE (operation S720).

Like this, when the battery 100 is being discharged, it is natural from the user's point of view to display the SOC value of the battery 100 as decreasing. When the battery 100 is being discharged, even if the SOC value of the battery 100 is actually calculated to temporarily increase because the load applied to the battery 100 is reduced and/or removed, if the SOC value of the battery 100 is displayed as increasing, the user may misunderstand and believe that the battery 100 is defective. Thus, when the battery 100 is being charged, the holding module 332D may set the SOC reported value SOC_RE to the previous SOC reported value SOC_RE_PRE in response to the SOC reported value SOC_RE being greater than the previous SOC reported value SOC_RE_PRE. As a result, as shown in IV of FIG. 5, when the SOC calculated value SOC_CAL increases during the discharging of the battery 100, the SOC reported value SOC_RE may remain constant without increasing.

In this way, by reducing and/or preventing the SOC reported value SOC_RE from increasing while the battery 100 is being discharged, it is possible to improve the confidence of the user of the electronic device 1 (see FIG. 1) and/or in the battery 100. In addition, in response to a decrease in the SOC reported value SOC_RE while the battery 100 is being discharged, the holding module 332D may set the previous SOC reported value SOC_RE_PRE to the SOC reported value SOC_RE and set the decreased SOC reported value SOC_RE as it is. Accordingly, when the battery 100 is being discharged, the SOC reported value SOC_RE may be displayed to the user of the electronic device 1 (see FIG. 1) as decreasing.

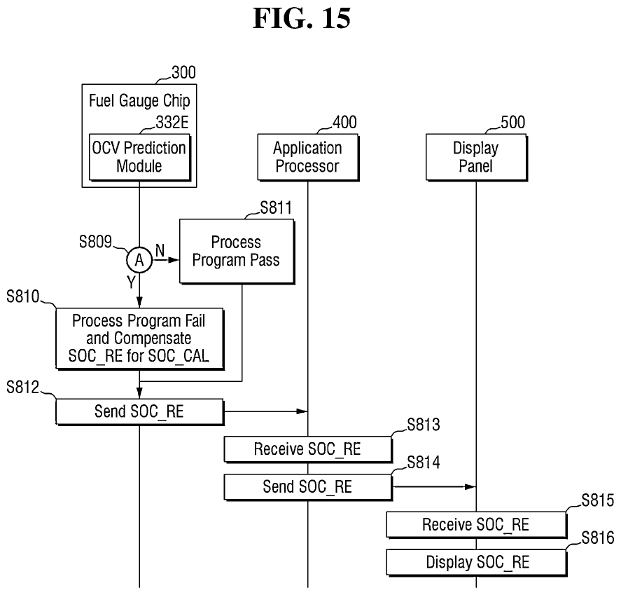

FIGS. 14 and 15 are flowcharts illustrating the operation of the electronic device 1 including the OCV prediction module 332E illustrated in FIG. 3 according to at least one example embodiment.

Referring to FIGS. 14 and 15, the sensing device 200 senses the battery condition information, e.g., the voltage, current and/or temperature of the battery 100 (operation S800) and sends the battery condition information, e.g., the sensed voltage, current and/or temperature to the SOC calculator 331 (operation S801). The SOC calculator 331 receives battery condition information about the and/or regarding the voltage, current, and/or temperature, etc., of the battery 100 (operation S802) and calculates the SOC calculated value SOC_CAL of the battery 100 based on the received battery condition information (operation S803). Then, the SOC calculator 331 sends the SOC calculated value SOC_CAL to the OCV prediction module 332E (operation S804).

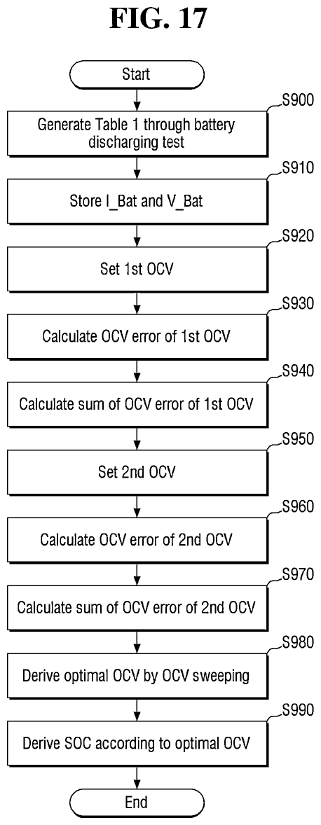

The OCV prediction module 332E receives the SOC calculated value SOC_CAL (operation S805), derives an optimal OCV (e.g., desired OCV threshold and/or desired OCV value, etc.) that decreases and/or minimizes an OCV error of the battery 100 (operation S806), and derives an SOC value according to the optimal OCV (operation S807). The operation of deriving the optimal OCV and the SOC value according to and/or based on the optimal OCV using the OCV prediction module 332E will be described later with reference to FIG. 17. Next, the OCV prediction module 332E compares the SOC value according to and/or based on the optimal OCV with the SOC calculated value SOC_CAL received from the SOC calculator 331 (operation S808). Then, the OCV prediction module 332E determines whether a difference between the SOC value according to and/or based on the optimal OCV and the SOC calculated value SOC_CAL is equal to or greater than a desired and/or preset threshold value (operation S809, node A). If OCV prediction module 332E determines that the difference is equal to or greater than the threshold value (Y in operation S809), the OCV prediction module 332E processes it as program fail and compensates the SOC reported value SOC_RE based on the SOC calculated value SOC_CAL to reduce and/or minimize the difference between the SOC calculated value SOC_CAL and the SOC value according to and/or based on the optimal OCV (operation S810), etc.

In some example embodiments, the SOC calculated value SOC_CAL may be corrected to increase and/or decrease by giving and/or applying a weight to the SOC calculated value SOC_CAL so that the difference between the SOC calculated value SOC_CAL and the SOC value according to and/or based on the optimal OCV is reduced and/or minimized. If OCV prediction module 332E determines that the difference is not equal to or greater than the threshold value (N in operation S809), the OCV prediction module 332E processes it as program pass (operation S811). Then, the OCV prediction module 332E sends the SOC reported value SOC_RE to the application processor 400 through I2C communication (operation S812). The application processor 400 receives the SOC reported value SOC_RE (operation S813) and sends the SOC reported value SOC_RE to the display panel 500 (operation S814), but is not limited thereto. The display panel 500 receives the SOC reported value SOC_RE (operation S815) and finally displays the SOC reported value SOC_RE (operation S816), but is not limited thereto.

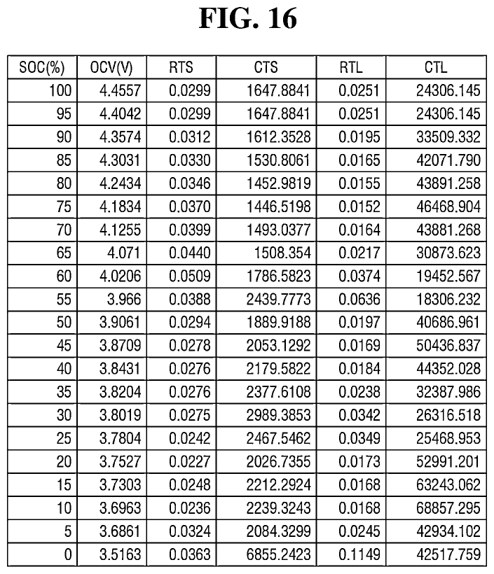

FIG. 16 is an example diagram for explaining the operation of the OCV prediction module 332E according to at least one example embodiment. FIG. 17 is a flowchart illustrating an operation of deriving an optimal OCV and an SOC value according to the optimal OCV using the OCV prediction module 332E according to at least one example embodiment.

First, referring to FIG. 16, in some example embodiments, Table 1 may be generated by the OCV prediction module 332E by storing an OCV value, a short term register (RTS) coefficient, a short term capacitor (CTS) coefficient, a long term register (RTL) coefficient, and/or a long term capacitor (CTL) coefficient, etc., at desired and/or predetermined intervals of the SOC value of the battery 100 through a preliminary battery discharging test, etc., but the example embodiments are not limited thereto. In a state where the OCV of the battery 100 may be measured because there is no load applied to the battery 100, the OCV value, the RTS coefficient, the CTS coefficient, the RTL coefficient, and/or the CTL coefficient, etc., may be derived and/or determined in advance for each SOC value, but the example embodiments are not limited thereto. In Table 1, the OCV value, the RTS coefficient, the CTS coefficient, the RTL coefficient, and the CTL coefficient are stored for the SOC value set at intervals of 5%. However, the example embodiments are not limited thereto, and the SOC value may also be set at any other interval (e.g., at intervals of 3%, etc.) to perform a preliminary battery discharging test.

As will be described later in FIG. 17, in some example embodiments, the OCV prediction module 332E (see FIG. 3) may derive an optimal OCV that decreases and/or minimizes an OCV error by using a correspondence relationship between the SOC value, the OCV value, the RTS coefficient, the CTS coefficient, the RTL coefficient, and/or the CTL coefficient, etc., generated through a preliminary battery discharging test. In addition, the OCV prediction module 332E (see FIG. 3) may derive an SOC value according to and/or based on the optimal OCV by using the result of the preliminary battery discharging test.

In some example embodiments, a battery voltage modeling equation for calculating an OCV error may be expressed as Equation 1.

$$OCV Error = OCVs - RTS * I\_Bat * exp ( - ( t\_rate ) / RTS / CTS ) - RTL * I\_Bat * exp ( - ( t\_rate ) / RTL / CTL ) - V\_Bat ( t ) \qquad [ Equation 1 ]$$

where OCVs is an initial OCV (first OCV) when an OCV value is swept, I_Bat is a current of the battery when current stabilization starts, V_Bat(t) is a voltage of the battery in a current stabilization state, t_rate is a desired and/or predetermined time interval, RTS is a short term register coefficient, CTS is a short term capacitor coefficient, RTL is a long term register coefficient, and CTL is a long term capacitor coefficient.

In some example embodiments, the optimal OCV that decreases and/or minimizes the OCV error of the battery 100 (see FIG. 1) may be derived by the OCV prediction module 332E while the OCV is swept within a desired and/or predetermined voltage range at desired and/or predetermined voltage intervals. For example, when it is assumed that a voltage range in which the OCV is swept is 10 mV and voltage intervals at which the OCV is swept is 0.15 mV, the optimal OCV that decreases and/or minimizes the OCV error may be searched for by the OCV prediction module 332E while the OCV value is swept from OCVs (e.g., a first OCV) to OCVs (e.g., first OCV)+10 mV at intervals of 0.15 mV, etc. However, the example embodiments are not limited thereto, and the voltage range and voltage intervals for sweeping the OCV may vary depending on the example embodiments. A case where the OCV is swept within the range of 10 mV at intervals of 0.15 mV will be described below as an example, but the example embodiments are not limited thereto.

Next, referring to FIG. 17, Table 1 (see FIG. 16) is generated by the OCV prediction module 332E by deriving OCV, RTS, CTS, RTL, and/or CTL, etc., at desired and/or predetermined intervals of the SOC value of the battery 100 through a preliminary battery discharging test (operation S900). Then, in a current stabilization state during discharging of the battery 100, the OCV prediction module 332E (see FIG. 3) stores the current (I_Bat) of the battery 100 at the start of the current stabilization state and stores N battery voltages (V_Bat) at desired and/or predetermined time intervals (t_rate) (operation S910). The current stabilization state refers to a state in which there is almost no current flowing through the battery 100 as shown in V of FIG. 5. For example, when an absolute value of an average current flowing through the battery 100 is 60 mA or less, this may correspond to the current stabilization state, but the example embodiments are not limited thereto.

Next, the OCV prediction module 332E sets an N^{th} V_Bat(t) as one or more OCVs (e.g., a first OCV, etc.) (operation S920), and RTS, CTS, RTL, and/or CTL values, etc., of the corresponding OCV value are found in Table 1 (see FIG. 16) and substituted into Equation 1, and the OCV prediction module 332E calculates an OCV error for each N number of V_Bat(t) (operation S930). Then, a first OCV error value is calculated by the OCV prediction module 332E by adding all of the squares of N OCV error values (operation S940), etc., but the example embodiments are not limited thereto.

Next, a value obtained by adding 0.15 mV to OCVs (first OCV) is set as a second OCV (operation S950) by the OCV prediction module 332E, and RTS, CTS, RTL and CTL, etc., corresponding to the second OCV are found in Table 1 illustrated in FIG. 16 and substituted into Equation 1 (the second OCV is substituted for OCVs) to calculate an OCV error for each N number of V_Bat(t) (operation S960), etc. Then, a second OCV error value is calculated by the OCV prediction module 332E by adding all of the squares of N OCV error values (operation S970), etc. This process is repeated to derive an optimal OCV (e.g., a desired OCV threshold, etc.) having a smallest OCV error while sweeping the OCV at desired and/or predetermined voltage intervals (operation S980). Then, an SOC according to the optimal OCV is derived using Table 1 (see FIG. 16) (operation S990).

In this way, in at least some example embodiments, a correspondence relationship between the OCV value and SOC value of the battery 100 may be derived, and/or may be derived in advance, through a preliminary battery discharging test, and the OCV prediction module 332E (see FIG. 3) may derive an optimal OCV that decreases and/or minimizes an OCV error and an SOC value according to the optimal OCV using N battery voltages, etc. Therefore, there is no need to wait for a long time until the load applied to the battery 100 (see FIG. 1) disappears in order to check an accurate SOC value of the battery 100 (see FIG. 1) while the electronic device 1 (see FIG. 1) performs an operation. Instead, it is possible to detect an error in the SOC calculated value SOC_CAL in a short time through OCV prediction and correct the SOC calculated value SOC_CAL to the SOC value according to the optimal OCV, etc.

While various example embodiments of the inventive concepts have been particularly illustrated and described with reference to example embodiments thereof, it will be understood by those of ordinary skill in the art that various changes in form and detail may be made therein without departing from the spirit and scope of the inventive concepts as defined by the following claims. The example embodiments described herein should be considered in a descriptive sense only and not for purposes of limitation.

What is claimed is:

1. An electronic device comprising:
a battery configured to supply power; and
processing circuitry configured to,
calculate a state of charge (SOC) calculated value of the battery based on sensed battery condition information of the battery,
generate an SOC reported value, which fluctuates between a desired first value and a desired second value based on at least one of the SOC calculated value, a charging status of the battery, a fully charged voltage of the battery, and a fully discharged voltage of the battery, the desired second value being lower than the desired first value, and
control the electronic device based on the SOC reported value.

2. The electronic device of claim 1, wherein the processing circuitry is further configured to:
determine a desired open circuit voltage (OCV) threshold based on the sensed battery condition information associated with a current stabilization state during a discharge operation of the battery; and
compare an SOC value according to the desired OCV threshold with the SOC calculated value.

3. The electronic device of claim 2, wherein the processing circuitry is further configured to:
determine whether a difference between the SOC value and the SOC calculated value are equal to or greater than a desired threshold value; and
correct the SOC calculated value to decrease a difference between the SOC calculated value and the SOC value based on results of the determination.

4. The electronic device of claim 1, wherein the processing circuitry is further configured to:
correct an amount of change in the SOC calculated value with respect to an amount of change in a used capacity of the battery based on the SOC calculated value and the charging status of the battery.

5. The electronic device of claim 4, wherein the processing circuitry is further configured to:
correct the amount of change in the SOC calculated value with respect to the amount of change in the used capacity of the battery in response to a decrease in a slope of the SOC calculated value being below a desired decreasing slope threshold value during a discharging operation of the battery.

6. The electronic device of claim 4, wherein the processing circuitry is further configured to:
correct the amount of change in the SOC calculated value with respect to the amount of change in the used capacity of the battery in response to an increase in a slope of the SOC calculated value being above a desired increasing slope threshold value while the battery is changed from a discharged state to a charged state.

7. The electronic device of claim 4, wherein the processing circuitry is further configured to:
correct the amount of change in the SOC calculated value with respect to the amount of change in the used capacity of the battery in response to a change in the fully discharged voltage of the battery.

8. The electronic device of claim 1, wherein the processing circuitry is further configured to:
repeatedly increase the SOC reported value by a desired percentage value in response to an average voltage of the battery being greater than the fully charged voltage and the SOC calculated value being smaller than the desired first value.

9. The electronic device of claim 1, wherein the processing circuitry is further configured to:
repeatedly decrease the SOC reported value by a desired percentage value in response to an average voltage of the battery being smaller than the fully discharged voltage and the SOC calculated value being greater than the desired first value.

10. The electronic device of claim 1, wherein the processing circuitry is further configured to:
set the SOC reported value to the desired first value in response to the SOC calculated value being greater than the desired first value.

11. The electronic device of claim 10, wherein the processing circuitry is further configured to:
correct an amount of change in the SOC calculated value with respect to an amount of change in the used capacity of the battery in response to the SOC calculated value decreasing below the desired first value.

12. The electronic device of claim 1, wherein the processing circuitry is further configured to:
set the SOC reported value to the desired second value in response to the SOC calculated value being smaller than the desired second value.

13. The electronic device of claim 12, wherein the processing circuitry is further configured to:
correct an amount of change in the SOC calculated value with respect to an amount of change in a used capacity of the battery in response to the SOC calculated value increasing above the desired second value.

14. The electronic device of claim 1, wherein the processing circuitry is further configured to:
correct the SOC reported value to a value before the SOC reported value decreases in response to a decrease in the SOC reported value in response to the battery being in a charging state.

15. The electronic device of claim 1, wherein the processing circuitry is further configured to:
correct the SOC reported value to a value before the SOC reported value increases in response to an increase in the SOC reported value in response to the battery being in a discharging state.

16. An electronic device comprising:
a battery configured to supply power;
a display panel configured to display a remaining capacity of the battery; and
processing circuitry configured to,
calculate a state of charge (SOC) calculated value of the battery based on sensed battery condition information of the battery,
generate a SOC reported value, the SOC reported value fluctuating between a desired first SOC value and a desired second SOC value, based on at least one of the SOC calculated value, a charging status of the battery, a fully charged voltage of the battery, and a fully discharged voltage of the battery, the desired first SOC value being greater than the desired second SOC value, and
display the SOC reported value on the display panel.

17. The electronic device of claim 16, wherein the processing circuitry is further configured to:
correct the SOC calculated value; and
provide the corrected SOC calculated value to the display panel.

18. The electronic device of claim 17, wherein the processing circuitry is further configured to:
calculate the SOC calculated value;
correct the SOC calculated value; and
correct an amount of change in the SOC calculated value with respect to an amount of change in a used capacity of the battery based on the SOC calculated value and the charging status of the battery.

19. An electronic device comprising:
a battery configured to supply power to the electronic device;
a sensing device configured to sense battery condition information of the battery;
processing circuitry configured to,
calculate a state of charge (SOC) calculated value of the battery based on the sensed battery condition information;
derive a desired open circuit voltage (OCV) threshold based on the sensed battery condition information while in a current stabilization state during a discharging operation of the battery,
compare an SOC value based on the desired OCV threshold with the SOC calculated value, and
correct an amount of change in the SOC calculated value with respect to an amount of change in a used capacity of the battery based on the SOC calculated value and a charging status of the battery; and
a display panel configured to display a remaining capacity of the battery based on the corrected amount of change in the SOC calculated value.

20. The electronic device of claim 19, wherein the processing circuitry is further configured to:
determine whether a difference between the SOC value and the SOC calculated value are equal to or greater than a desired threshold value; and
correct the SOC calculated value to decrease a difference between the SOC calculated value and the SOC value based on results of the determination.
